(19) United States
(12) Patent Application Publication
(10) Pub. No.: US 2019/0242838 A1
(43) Pub. Date: Aug. 8, 2019

(54) Non-Invasive Method for Probing Plasma Impedance

(71) Applicant: The Government of the United States of America, as represented by the Secretary of the Navy, Arlington, VA (US)

(72) Inventors: Eric D. Gillman, Grosse Pointe Park, MI (US); Erik M. Tejero, Falls Church, VA (US); David Blackwell, Alexandria, VA (US); William E. Amatucci, Fairfax, VA (US)

(73) Assignee: The Government of the United States of America, as represented by the Secretary of the Navy, Arlington, VA (US)

(21) Appl. No.: 16/266,150

(22) Filed: Feb. 4, 2019

Related U.S. Application Data
(60) Provisional application No. 62/647,860, filed on Mar. 26, 2018.
(60) Provisional application No. 62/627,221, filed on Feb. 7, 2018.

(51) Int. Cl. G01N 27/02; G01R 27/28

(52) U.S. Cl. CPC G01N 27/028; G01R 27/28

(57) ABSTRACT

A method for non-invasively measuring the impedance of a plasma discharge. Parallel anode and cathode electrodes are connected to a DC voltage source that ignites and sustains a plasma between the anode and cathode. A network analyzer applies a frequency-swept AC signal superimposed onto the DC voltage applied to the electrodes. The voltage of the AC signal reflected by the plasma is measured by the network analyzer through one of the electrodes used to sustain the plasma and is used to find the complex impedance of the plasma as a function of the applied AC frequency. Since the electrode serves dual purposes, the insertion of an additional physical probe that could introduce perturbations or contaminate the discharge is not necessary.

### CROSS-REFERENCE

This Application is a Nonprovisional of, and claims the benefit of priority under 35 U.S.C. § 119 based on, U.S. Provisional Patent Application No. 62/627,221 filed Feb. 7, 2018, and U.S. Provisional Patent Application No. 62/647,860 filed Mar. 26, 2018. The Provisional Applications and all references cited herein are hereby incorporated by reference into the present disclosure in their entirety.

### TECHNICAL FIELD

The present disclosure relates to an apparatus and method for non-invasively measuring the impedance of a plasma discharge.

### BACKGROUND

Langmuir probes are widely considered the standard in low-temperature plasma discharge diagnostics. Langmuir probes are a relatively reliable diagnostic due to their robustness, simple construction, and quick implementation. However, the difficulty and complexity with Langmuir probes becomes apparent in analyzing and interpreting the results of discharges with non-Maxwellian or non-ideal current-voltage characteristics. See, e.g., M. Sugawara, “Electron Probe Current in a Magnetized Plasma,” The Physics of Fluids 9, 797 (1966). Additionally, Langmuir probes require insertion of a physical probe into the discharge. Such insertion can be challenging for plasmas in environments such as fusion devices and plasma materials processing reactors. In addition, insertion of a probe into a plasma can perturb or even contaminate the plasma, thereby affecting the measurements obtained.

Several non-invasive plasma measurement methods such as microwave interferometry, microwave cutoff, Laser-Induced Fluorescence (LIF), and optical emission methods have been developed to address these issues. However, each of these non-invasive methods have limitations including requiring optical access, and can be relatively difficult to employ depending on the discharge geometry.

### SUMMARY

This summary is intended to introduce, in simplified form, a selection of concepts that are further described in the Detailed Description. This summary is not intended to identify key or essential features of the claimed subject matter, nor is it intended to be used as an aid in determining the scope of the claimed subject matter. Instead, it is merely presented as a brief overview of the subject matter described and claimed herein.

The present invention provides a non-invasive method for measuring plasma impedance wherein an electrode used to ignite and sustain the plasma is also used as an impedance probing device. The plasma impedance found using the non-invasive method of the present invention can then be used to find parameters of the plasma such as plasma electron density, plasma potential, and plasma temperature.

In accordance with the present invention, two parallel plates are connected to a DC voltage source and are used as electrodes to ignite and sustain a DC glow discharge plasma between the anode and cathode. A network analyzer applies a small frequency-swept AC signal that is superimposed onto the DC discharge bias applied to the electrodes. A capacitor situated between the network analyzer and the electrodes is used to isolate the network analyzer from the discharge bias signal while still allowing passage of the frequency-swept AC signal to the anode. The reflected complex impedance is measured through one of the electrodes used to sustain the discharge and input into the network analyzer, with the magnitude and phase of this complex impedance being found as a function of the applied AC frequency. Since the electrode that is used ignite and sustain the plasma is used to measure the impedance, the insertion of an additional physical probe that could introduce perturbations or contaminate the discharge is not necessary.

The method of the present invention can also be used to provide measurement of plasma free electron density and plasma electron temperature

### BRIEF DESCRIPTION OF THE DRAWINGS

FIG. 1 is a block schematic illustrating an exemplary configuration of components used to implement a non-invasive plasma impedance probing method in accordance with one or more aspects of the present invention.

FIG. 2 is a plot illustrating exemplary DC and AC voltages applied to an anode used in a non-invasive method for probing plasma impedance in accordance with one or more aspects of the present disclosure.

FIG. 3 is a block schematic illustrating an exemplary RLC circuit that models a plasma discharge and can be used to calculate plasma parameters from the complex impedance measured using a non-invasive method for probing plasma impedance in accordance with one or more aspects of the present invention.

FIGS. 4A-4D are plots illustrating the characteristics of a non-collisional and collisional plasma discharge when modeled as an ideal RLC circuit, where FIGS. 4A and 4B show the real and imaginary parts of the complex impedance and FIGS. 4C and 4D show the complex impedance in terms of its magnitude and phase.

FIGS. 5A and 5B are plots illustrating experimental measurements of the complex impedance, where FIGS. 5A and 5B show the real and imaginary parts of the complex impedance and FIGS. 5C and 5D show the complex impedance in terms of its magnitude and phase.

FIGS. 6A-6C are plots illustrating the dependency of the resonant feature's shape (width and magnitude) on neutral gas pressure, which is directly related to the collision frequency.

FIG. 7 is a plot illustrating the correlation of electron density as measured by a traditional Langmuir probe and by this non-invasive impedance probing method.

### DETAILED DESCRIPTION

The aspects and features of the present invention summarized above can be embodied in various forms. The following description shows, by way of illustration, combinations and configurations in which the aspects and features can be put into practice. It is understood that the described aspects, features, and/or embodiments are merely examples, and that one skilled in the art may utilize other aspects, features, and/or embodiments or make structural and functional modifications without departing from the scope of the present disclosure.

The present invention is based on impedance probe diagnostic work previously done by the inventors David Blackwell and William Amatucci together with David Walker and others at the Naval Research Laboratory. See e.g., D. D. Blackwell, D. N. Walker, and W. E. Amatucci, “Measurement of absolute electron density with a plasma impedance probe,” Rev. Sci. Instrum. 76, 023503 (2005) (“Blackwell 2005”); D. D. Blackwell, D. N. Walker, S. J. Messer, and W. E. Amatucci, “Characteristics of the plasma impedance probe with constant bias” Physics of Plasmas 12, 093510 (2005); D. N. Walker, R. F. Fernsler, D. D. Blackwell, and W. E. Amatucci, “Determining electron temperature for small spherical probes from network analyzer measurements of complex impedance,” Physics of Plasmas 15, 123506 (2008); D. N. Walker, R. F. Fernsler, D. D. Blackwell, and W. E. Amatucci, “Using rf impedance probe measurements to determine plasma potential and the electron energy distribution,” Physics of Plasmas 17, 113503 (2010); and D. N. Walker, D. D. Blackwell, and W. E. Amatucci, “Electron density dependence of impedance probe plasma potential measurements,” Physics of Plasmas 22, 083505 (2015).

In accordance with the non-invasive method for probing plasma impedance in accordance with the present invention, and unlike the probing methods explored in these previous works, insertion of a physical probe to measure impedance is not required. Instead, an electrode already necessary to sustain a discharge is also used to probe the plasma discharge impedance.

As described in more detail below, two parallel plates are connected to a DC voltage source and are used as anode and cathode electrodes to ignite and sustain a DC glow discharge plasma between the anode and cathode. In accordance with the present invention, a network analyzer then applies a small frequency-swept AC signal to the plasma, the AC signal being superimposed onto the DC discharge bias applied to the electrodes to form the plasma. A capacitor situated between the network analyzer and the plasma is used to isolate the network analyzer from the discharge bias signal while still allowing passage of the frequency-swept AC signal to the anode. The complex impedance of the plasma discharge is measured through one of the electrodes used to sustain the discharge and input into the network analyzer, with the magnitude and phase of this complex impedance being found as a function of the applied AC frequency. Since the electrode that is used ignite and sustain the plasma is used to measure the impedance, the insertion of an additional physical probe that could introduce perturbations or contaminate the discharge is not necessary.

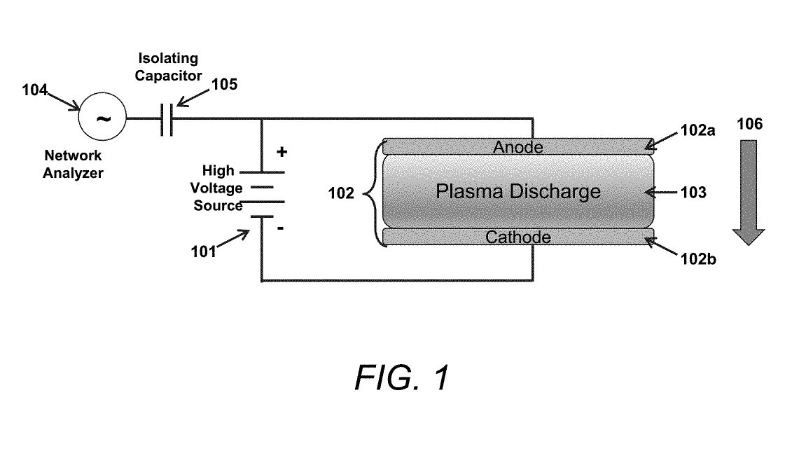

FIG. 1 illustrates an exemplary configuration of components that can be used to implement a non-invasive method for probing plasma impedance in accordance with the present disclosure.

Thus, as shown in FIG. 1, a non-invasive method for probing plasma impedance in accordance with the present invention can be accomplished by using a high voltage source 101 coupled to a parallel plate capacitor 102 comprising an anode 102a and a cathode 102b, a vector network analyzer 104 coupled to the anode 102a, and an isolating capacitor 105 situated between the network analyzer 104 and the anode 102a.

High voltage source 101 supplies current and maintains a high potential between anode 102a and cathode 102b to ignite and sustain a plasma discharge 103 contained between the electrodes. In some embodiments, high voltage source 101 can be coupled to both the anode and the cathode, while in other embodiments, it may be coupled to only one or other of them.

A vector network analyzer 104 is connected to anode 102a, with isolating capacitor 105 serving to isolate the network analyzer from the high voltage signal supplied to the anode. In some embodiments, anode 102a is biased to a small positive potential by a current sink source to prevent the frequency-swept signal from shorting to ground, while cathode 102b is biased to a large negative potential. In other embodiments, high voltage power supply 101 could be used to simply bias anode 102a and cathode 102b relative to each other, or anode 102a could be biased at a high positive potential while cathode 102b is grounded, with the network analyzer 104 being connected in the same way.

In addition, in order to obtain accurate complex impedance measurements, network analyzer 104 should be calibrated to remove stray capacitance and inductance in the cabling and circuitry coupled to anode 102a.

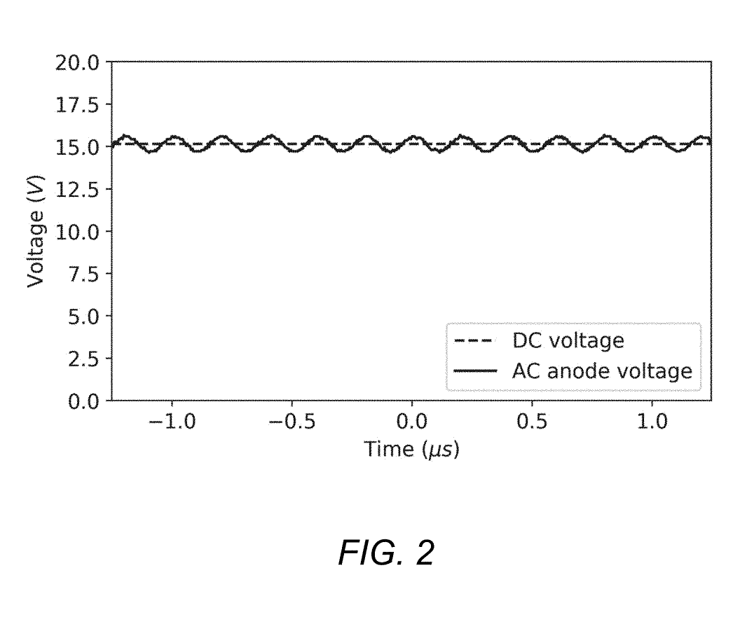

In accordance with the method of the present invention, network analyzer 104 supplies a small AC signal to the plasma, superimposed on the DC signal at a plurality of predetermined frequencies over a predetermined frequency range. The waveform plot shown in FIG. 2 illustrates one such applied signal, showing a waveform resulting from application of a 1 V peak-to-peak sinusoidal AC signal having a frequency of 5 MHz superimposed on top of a +15 V DC signal that is supplied by the DC voltage source.

This AC signal is reflected back to the network analyzer via the anode and, simultaneously with the application of the AC signal, the voltage of the reflected signal is measured by the network analyzer as a function of time. Reflections of the applied AC signal can occur due to mismatched impedance of electrical components including circuit elements and cables, as well as from the plasma discharge. To account for these additional components, reflections due to impedance mismatches other than the plasma itself are calibrated out of the measurements ahead of time using standard network analyzer calibration procedures well known in the art, so that the signal reflections that are measured by the network analyzer and used in the plasma probing method of the present invention are due only to impedance mismatches between the electrodes and the plasma discharge itself.

This reflected signal at each frequency is quantified as the complex impedance of the plasma at that frequency. The way in which the plasma responds to and reflects these AC signals of various frequencies changes with frequency, with the complex impedance of the plasma discharge changing as the frequency of the AC signal changes. At particular frequencies known as the resonant frequencies, the plasma has a very sharp response. When these resonant frequencies are applied, the plasma response changes the reflected AC signal and therefore the complex impedance. The frequency at which this resonance occurs is dependent on the parameters of the plasma discharge. Therefore, the network analyzer is used to make many discrete measurements of the plasma discharge impedance over a predetermined and specified range of frequencies.

This impedance can be expressed as either the real and imaginary impedance or as the impedance magnitude and phase using a simple and well-known mathematical conversion between the two. Thus, by measuring the voltage of the reflected signal versus the voltage of the applied signal, the complex impedance of the plasma can be easily deduced by standard and well-known AC electrical practices.

The complex impedance measurements thus obtained non-invasively in accordance with the present invention can be recorded in any number of standard data file formats and then be input into a processor algorithm to find the two plasma resonant frequencies, ωᵣₑₛ₁ and ωᵣₑₛ₂=ωₚₑ, which in turn can then be used to find plasma parameters such as plasma electron density, plasma potential, and plasma electron temperature.

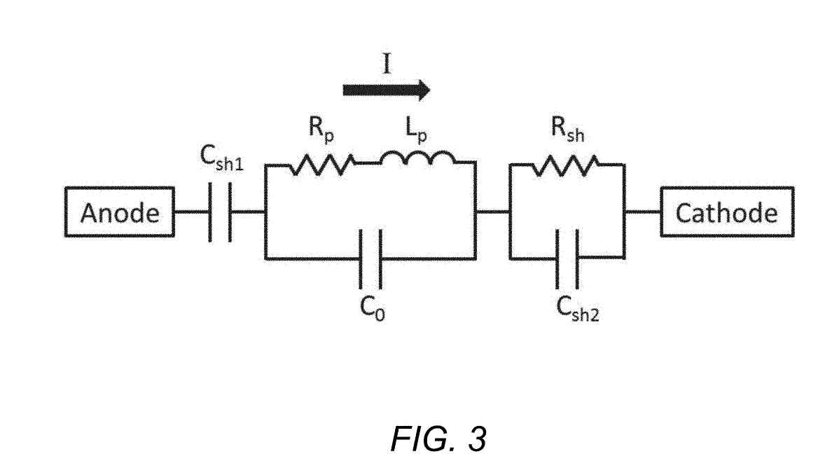

The plasma discharge can be modeled as a combination of electrical circuit components, as shown in FIG. 3.

In such an RLC circuit, the anode and cathode form a parallel plate capacitor with a known capacitance

$${C}_{0} = \frac{{ɛ}_{0} aA}{d} \qquad ( 1 )$$

where ε₀, aA and d are the vacuum permittivity, area of the discharge electrodes, and separation distance of the electrodes, respectively.

Sheaths form at surfaces where an object contacts a plasma discharge. These sheaths vary greatly from the bulk plasma, but well-known relationships have been made between the properties of the sheath and the bulk plasma.

In FIG. 3, Cₛₕ₁ represents the capacitance across the anode sheath, and the “series” resonance occurs at the frequency where the impedance magnitude is lowest. At the series resonant frequency, the AC signal is efficiently passed across the anode sheath (Cₛₕ₁) and is absorbed by the bulk plasma. The result is a very small signal reflected back to the network analyzer, meaning a low impedance. This resonance is observed by finding the frequency where the impedance is at a minimum (ωᵣₑₛ₁).

The parallel resonance occurs when the internal capacitance and inductance of the plasma is in resonance, meaning that very little of the AC energy is absorbed by the discharge. The parallel resonant frequency is equal to the plasma electron oscillation frequency in the collisionless case (ωᵣₑₛ₂=ωₚₑ). The plasma electron oscillation frequency (ωₚₑ) is a well-known expression that is dependent only on physical constants and the plasma electron density ωₚₑ=\sqrt{(nₑe²)/(mₑε₀)}l . At this oscillation frequency, most of the AC signal is reflected, and this frequency is apparent where the magnitude of the reflected impedance is at a maximum.

The impedance (Z) of such a modeled RLC circuit can be calculated as

$$Z = - j \frac{1}{ω {C}_{sh 1}} + {[ j ω {C}_{0} + \frac{1}{{R}_{p} + j ω {L}_{p}} ]}^{- 1} + {[ \frac{1}{{R}_{sh}} + j ω {C}_{sh 2} ]}^{- 1} \qquad ( 2 )$$

where ω, Cₛₕ₁, Rₛₕ, and Cₛₕ₂ are the AC signal angular frequency, anode sheath capacitance, cathode sheath resistance, and cathode sheath capacitance, respectively, and C₀, Rₚ, and Lₚ are the electrode capacitance, bulk plasma resistance, and bulk plasma inductance, respectively. According to the model used in Blackwell 2005, supra, Lₚ=1/(ωₚₑ²C₀) and Rₚ=νLₚ=ν/(ωₚₑ²C₀), where ωₚₑ and ν are the electron plasma frequency and electron collision frequency, respectively. See M. A. Lieberman and A. J. Lichtenberg, in Principles of Plasma Discharges and Materials Processing (John Wiley Sons, Inc., 2005, pp. 398-399.

Normalizing the variables so that γ=ω/ωₚₑ and δ=ν/ωₚₑ and simplifying the expression, the real and imaginary parts of the impedance can be expressed as

$$\begin{matrix}Re ( Z ) = \frac{δ}{{ω}_{p e} {C}_{0} ( {( {γ}^{2} - 1 )}^{2} + {γ}^{2} {δ}^{2} )} + \frac{{R}_{sh}}{1 + {ω}_{pe}^{2} {γ}^{2} {C}_{sh 2}^{2} {R}_{sh}^{2}} & ( 3 ) \\ Im ( Z ) = - \frac{{C}_{0} ( {( {γ}^{2} - 1 )}^{2} + {γ}^{2} {δ}^{2} ) + {C}_{sh 1} ( ( {γ}^{2} - 1 ) {γ}^{2} + {γ}^{2} {δ}^{2} )}{{ω}_{pe} γ {C}_{0} {C}_{sh 1} ( {( {γ}^{2} - 1 )}^{2} + {γ}^{2} {δ}^{2} )} - \frac{{ω}_{pe}^{2} {γ}^{2} {C}_{sh 2}^{2} {R}_{sh}^{2}}{1 + {ω}_{pe}^{2} {γ}^{2} {C}_{sh 2}^{2} {R}_{sh}^{2}} & ( 4 )\end{matrix}$$

The series and parallel resonances occur when frequency of the applied AC signal results in the imaginary part being equal to zero, or when the imaginary part of the impedance is at a local maximum or minimum closest to zero.

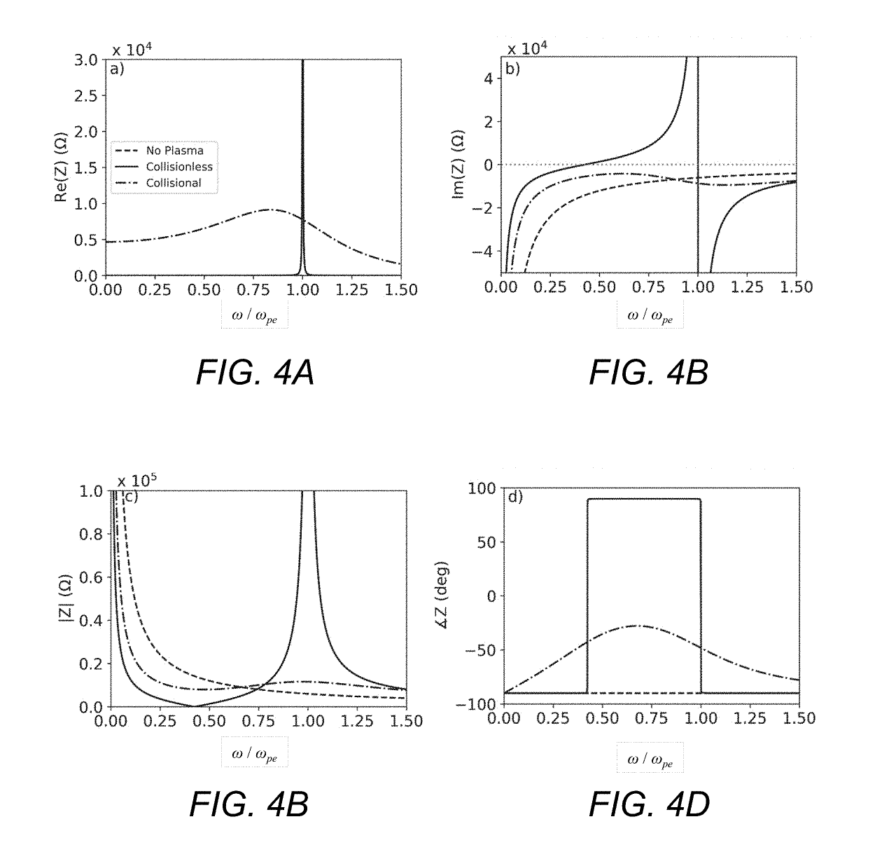

The plots in FIGS. 4A-4D illustrate an exemplary modeled impedance of the anode/cathode electrodes in a setup such as that illustrated in FIG. 1, for the case where there is no plasma between the electrodes (“No Plasma”), as well as for the case of a modeled collisionless plasma with nominal parameters (“Collisionless”) and for a modeled plasma having parameters typical of those used in experiments conducted by the Inventors (“Collisional”). For both of the modeled plasma cases, the electron density and temperature are given as nₑ=10⁶ cm⁻³ and Te=1.5 eV, respectively, with a pressure of 80 mTorr of Argon is given for the modeled collisional case.

In the collisionless modeled plasma, the resonances can be easily identified from both the magnitude and phase of the impedance or from the real and imaginary parts shown in the plots in FIGS. 4A-4D, where FIG. 4A shows the real part of the impedance, FIG. 4B, shows the imaginary part, FIG. 4C shows the magnitude, and FIG. 4D shows the phase.

As illustrated in FIG. 4A, when the real part of the modeled impedance for the collisionless plasma is at a local maximum, the plasma is at resonance, i.e., ω/ωₚₑ=1. Similarly, as shown in FIG. 4B, in such a collisionless case, the imaginary part of the impedance crosses zero at two points. The second zero crossing corresponds to a maximum in the real part of Z. This is the parallel resonance. The first zero crossing of the imaginary part of Z occurs when the real part of Z is at a minimum, and corresponds to the series resonance. In the collisional case shown by the plots in FIGS. 4A and 4B, collisions in the plasma result in a significant damping of both the real and imaginary features associated with the resonances. The collisions also shift the local maximum and minimum in the real and imaginary parts of Z to lower frequencies. In these cases the plasma electron oscillation frequency is actually slightly higher than the apparent parallel resonant frequency.

Resonances can also be observed by analyzing the impedance magnitude and phase, shown in FIGS. 4C and 4D, respectively. As can be seen from the plots in FIG. 4C, the minimum and maximum in the magnitude is clear for the collisionless case. Additionally, by observing the sharp phase shifts from −90 to +90 degrees and back shown in FIG. 4D, identification of the series and parallel resonances is simple for the collisionless case. Once again, however, collisions damp out the resonant features in both the magnitude and phase of the impedance when collisions are included.

### EXAMPLES

The inventors of the present invention performed experiments to demonstrate the noninvasive impedance probing method for extracting the plasma discharge density at various neutral gas pressures and discharge voltages and currents from changes to the input impedance of the anode in accordance with the present invention. The experiments were performed at the U.S. Naval Research Laboratory's Dusty PLasma EXperiment Junior (DUPLEX JR) vacuum facility. The vacuum chamber used consisted of a large cylindrical acrylic section 62 cm tall and 45 cm in diameter, mounted on top of a steel chamber and evacuated with a diffusion pump backed by a roughing pump capable of reaching base pressures below 10⁻⁵ Torr. The chamber was sealed on top with an aluminum lid with multiple vacuum feedthrough ports. The experiments were performed at several different pressures in an Argon gas environment, with the magnetic field set to 180 Gauss to create a stable discharge. While in some geometries a correction factor is required to account for a magnetic field, no correction was required in the given geometry since the magnetic field was parallel/antiparallel to the ion/electron drift and originated and terminated perpendicular to the electrode surface. See D. D. Blackwell, D. N. Walker, S. J. Messer, and W. E. Amatucci, “Antenna impedance measurements in a magnetized plasma. i. spherical antenna,” Phys. Plasmas 14, 092105 (2007); and D. D. Blackwell, D. N. Walker, S. J. Messer, and W. E. Amatucci, “Antenna impedance measurements in a magnetized plasma. ii. dipole antenna,” Phys. Plasmas 14, 092106 (2007). This was also tested and verified experimentally.

Two polished circular discs approximately 23 cm in diameter were used to form a parallel plate discharge with the electrodes separated by 12.5 cm. The electrodes were arranged as illustrated in FIG. 1. The bottom electrode was used as the cathode and was biased at −250 to −350V relative to the electrically grounded chamber, while the top electrode was used as the anode and is held at a relatively low positive DC voltage by a power supply that is referred to as a “current sink source.” Two electromagnets in a Helmholtz configuration applied a relatively uniform magnetic field up to 180 Gauss along the vertical axis in the center of the chamber, parallel to the electrode surface normal vector.

The discharge impedance was measured at several specified Argon gas pressures from about 80 to 200 mTorr. As noted above, higher pressures result in a greater number of collisions and a higher collision frequency. These collisions cause broadening of the plasma impedance features as compared to the collisionless plasma case, as shown by the plots in FIGS. 4A-4D. In the collisional cases, it is not so easy to pick the exact resonant frequencies by eye, especially since the imaginary part of the impedance never crosses zero. The impedance maximum and minimum also shift slightly from the collisionless resonant frequencies. This is why precisely measuring the complex impedance in collisional cases is so important.

Since it is obvious from the plots in FIGS. 4A-4D that it is very difficult to determine the resonant frequencies in a plasma in a collisional pressure regime as in the inventors' experiments, a numerical method for fitting the model curve to the experimental data was developed and implemented to get more accurate measurements of the plasma resonant frequencies, and thereby the plasma parameters. In the exemplary case used by the inventors in their experiments, a computer code was implemented with the fitting routine relying on a Levenberg-Marquardt algorithm well known in the art, but any suitable numerical fitting routine can be used to fit empirical measurements to those of a modeled plasma.

While calibration of the network analyzer significantly improved the measured impedance, especially in the case with no plasma, there were still some irregular variations. Measurements were performed by averaging 50 consecutive frequency sweeps. Measurements were taken for each case with no background gas (e.g., no plasma) and with the plasma on. A proper fit was found by removing the systematic noise and irregularities, performing the fitting routine, and then adding the fit to the baseline case (with no plasma). Additionally, in all cases, the response at low frequencies was not ideal. This was likely caused by effects of the isolating capacitor used to connect the network analyzer to the anode that were not able to be removed through the calibration. So the fit was performed at frequencies typically above approximately 4 MHz.

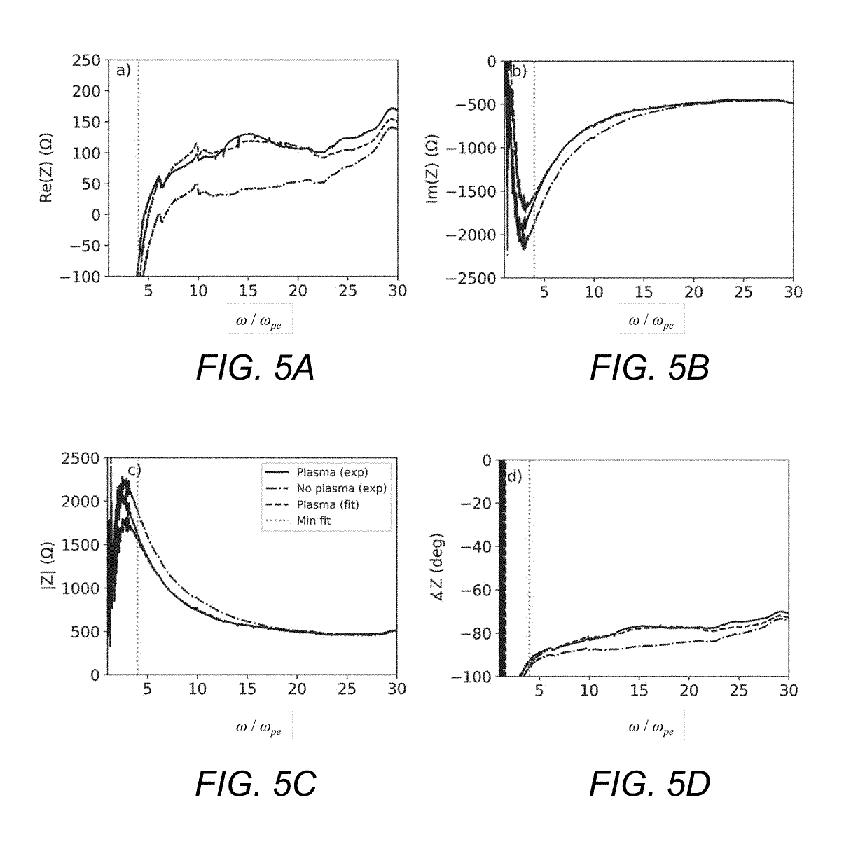

The plots in FIGS. 5A-5D show the real (FIG. 5A) and imaginary (FIG. 5B) parts of the impedance Z, as well as its magnitude (FIG. 5C) and phase (FIG. 5D) plotted as a function of frequency. The experimental data (solid lines) and fit to the data (dashed line) are plotted for both the case with a plasma (solid lines) and without a plasma (dash-dot line). The frequencies used for the fitting routine start at 4 MHz (dotted line) and go up to 30 MHz.

Each plot in FIG. 5 shows the real and imaginary parts of the experiment when no plasma is present and when the plasma is present. The difference between the no plasma and plasma case is due to the plasma resonance effects. These resonances can most easily be seen by looking at the magnitude and phase of the plasma impedance. At lower frequencies, the plasma reduces the impedance and the phase begins to shift towards positive values, and this corresponds to the series resonance. At higher frequencies, the plasma causes an increase in the impedance, and the phase shifts back towards greater negative values. This phenomenon is due to the parallel resonance.

The free parameters in the fit were electron density, electron temperature, and sheath thickness in number of Debye lengths. The rest of the parameters in the model were measured (pressure, electrode dimensions, etc.) or derived. For example, the electron collision frequency was calculated from the neutral pressure and electron temperature. The electron temperature was used to calculate the electron-neutral cross-section by assuming a Maxwellian distribution and integrating over the cross-sectional curve. See Lieberman, supra. The result of the fit gave reasonable values for the cross-section and electron collision frequency.

Varying Pressures

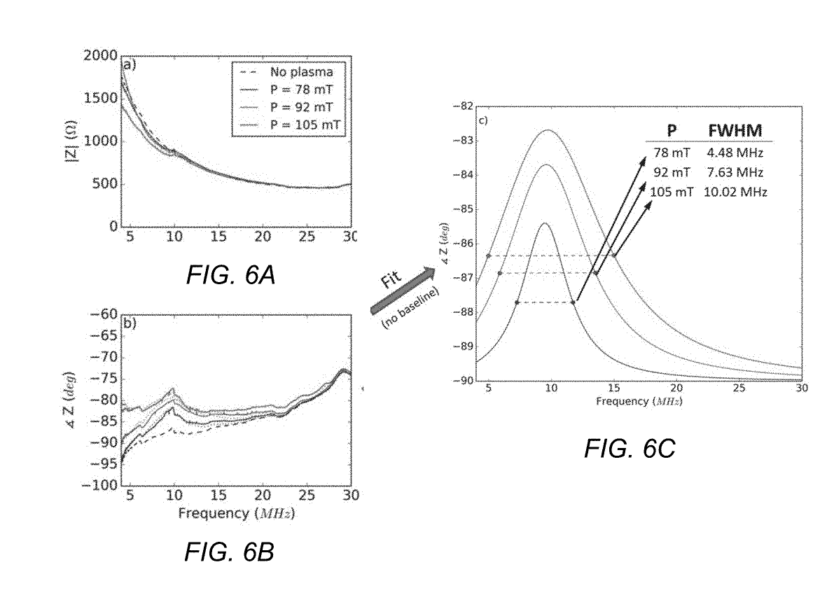

It was noted that the mathematical model predicted significant smoothing of the resonant features with increased collisionality. To ascertain this effect, measurements were taken at various pressures, where the collisionality would generally increase with increasing pressure. FIGS. 6A-6C show the experimental data and the numerical fit on the left (FIGS. 6A and 6B), along with the numerical fit to the phase of the impedance data without the experimental or systematic noise (FIG. 6C) for three different pressures. It is clear that as the pressure (and collision frequency) increases, the full-width half-maximum of the shift in phase increases significantly.

The fit in most cases was extremely accurate, as is the case shown in FIGS. 6A-6C, which shows the experimental and numerical fit data with the baseline (FIGS. 6A and 6B) as well as the numerical fit of phase with no baseline (FIG. 6C), and show a widening of the phase shift with increasing pressure.

This fit accurately reflects the measured impedance in terms of both the real and imaginary parts, as well as the magnitude and phase.

While the maximum in the phase shift for these cases occurs near the same frequency, the electron density predicted by the numerical fit increases with increasing pressure. Since more electrons are available to oscillate at the resonant frequencies and the phase shifts are slightly further apart, a slightly greater peak value in the phase shift is observed for increasing pressure.

Comparison with Langmuir Probe Measurements

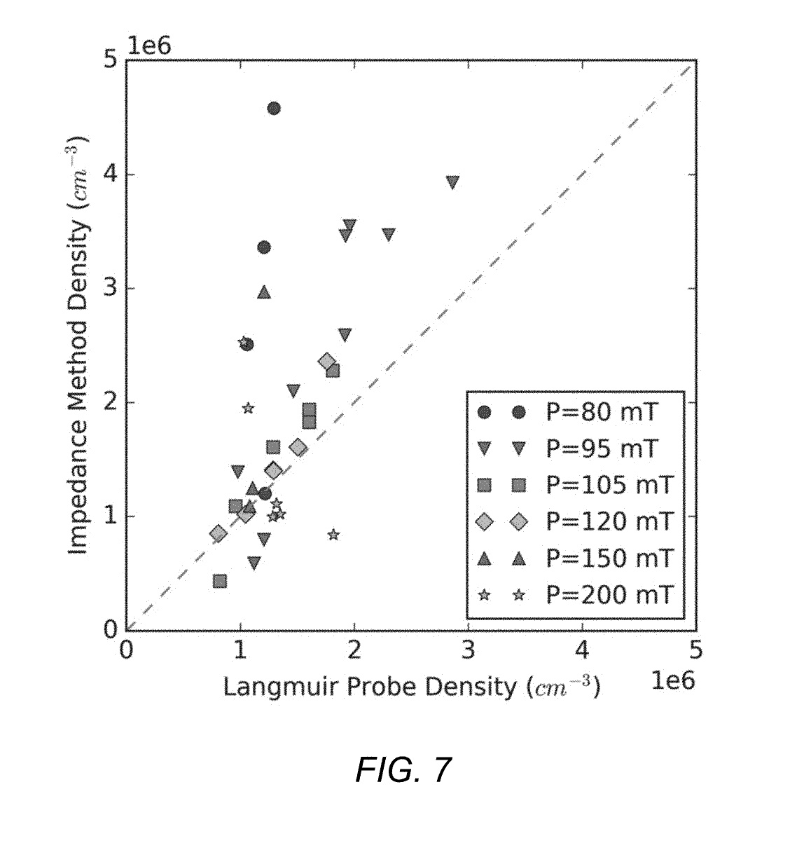

The plots in FIG. 7 show a comparison of plasma density measurements made by a conventional Langmuir probe and by the non-invasive impedance plasma density measurements in accordance with the present disclosure. As can be seen from the plots, in most cases, the plasma density measurements made by the method of the present invention show good agreement with those made by conventional invasive methods.

The Langmuir probe measurements were taken by inserting a cylindrical Langmuir probe 7.5 cm above the cathode (approximately in the positive column), on axis between the parallel plate electrodes for all cases.

FIG. 7 shows the electron density as measured by the impedance probe as a function of the Langmuir probe measured density. Points that lie on the dashed line are density measurements that are in exact agreement. For cases that are not very close in agreement, the density as measured by the impedance probe is greater than the density as measured by the Langmuir probe. Error between the density measurement methods varied, with a mean and median of 29.0% and 25.5%, which are very reasonable considering the characteristics that contributed to the Langmuir probe measurement error.

While the non-invasive impedance measurements don't exactly match the Langmuir probe results, we cannot conclusively determine which is more accurate. Error naturally exists in both measurements. The main advantage of the present invention is the ability to perform this measurement non-invasively, thereby not perturbing or contaminating the discharge or any processes occurring in the discharge.

Advantages and New Features

A non-invasive method for measuring the impedance of a DC glow discharge has been described. Unlike with previous impedance probes, see Blackwell 2005, supra, in the impedance probing method of the present invention, the physical insertion of a probe into the plasma to measure its plasma impedance is not necessary. Instead, one of the electrodes that is already present to sustain the discharge is supplied with a small frequency-swept AC signal superimposed on the DC bias to measure the plasma discharge's complex impedance. In this way, the plasma discharge impedance magnitude and phase are measured as a function of frequency. The discharge can be modeled as a resonant RLC circuit, where the resonant characteristics reveal the plasma parameters, in particular the plasma electron density.

Experimental measurements were made at several neutral gas pressures, and several discharge voltages and currents. A numerical method was used to fit the mathematical model to the data, and to get best fit values for the plasma electron density. These values were then compared to Langmuir probe measurements of the ion density. There was overall good agreement in plasma density measurements between the Langmuir probe and the impedance diagnostic method introduced here.

This non-invasive impedance measurement method has significance and utility for a wide array of various types of discharges such as capacitively and inductively coupled RF discharges, with more sophisticated filtering techniques required to isolate the network analyzer. This method can also be employed in miniaturized discharges where probe insertion is not possible and in negative ion or multiply ionized gas discharges. It should also be emphasized that this method can be used with gas mixtures including reactive gases, electronegative gases, and molecular gases.

Current investigations are underway that will focus on implementing this diagnostic method to measure the electron density in a dusty or complex plasma environment. Typically, electron populations are largely depleted in these discharges by collection on microparticle surfaces. Conventional diagnostics are not feasible and there are currently very few, if any diagnostics capable of measuring the electron density in these types of discharges. This impedance diagnostic method can be a reliable, non-invasive diagnostic that will directly measure the electron density in these types of discharges. Preliminary evidence suggests that the impedance probe is a reliable diagnostic in dusty or complex plasmas as well.

### Alternative Embodiments

In the exemplary case described herein, parallel plate electrodes were used to create the plasma discharge; however, the geometrical shape of the electrodes is not critical, and electrodes having any shape and configuration that can create a plasma discharge may be suitable.

While a vector network analyzer was used in these experiments to supply a frequency-swept AC signal and measure the complex impedance, any instrument capable of providing a frequency-swept signal and measuring complex impedance could be used for employing this impedance measurement method.

In the example outlined above, the anode was used as the probing electrode. However, either the anode or cathode, or discharge antenna (for RF discharges, see below) could be used to employ this same non-invasive complex impedance measurement.

Finally, although the inventors' experiments were performed with a DC glow discharge, this method could be employed to find the impedance in an RF discharge at any frequency. In such cases, the network analyzer or other instruments used to make the impedance measurement would require a notch rejection filter (rather than a simple capacitor) tuned to reject the RF frequency used to ignite and sustain the discharge (typically 13.56 MHz).

Although the present invention has been described with respect to particular illustrated embodiments, aspects, and features, one skilled in the art would readily appreciate that the invention described herein is not limited to only those embodiments, aspects, and features, but also contemplates any and all modifications and alternative embodiments that are within the spirit and scope of the underlying invention described and claimed herein. Thus, the present disclosure contemplates any and all modifications within the spirit and scope of the underlying invention described and claimed herein, and all such modifications and alternative embodiments are deemed to be within the scope and spirit of the present invention.

What is claimed is:

1. A method for non-invasively measuring an impedance of a plasma, comprising:
applying a DC voltage to an anode and a cathode of a capacitor to ignite and sustain a plasma between the anode and the cathode;
using a network analyzer coupled to one of the anode and the cathode, applying a plurality of AC signals to the plasma, the AC signals being superimposed onto the DC voltage and being applied at a predetermined plurality of frequencies in a predetermined frequency range, the plasma reflecting each of the AC signals to produce a plurality of reflected AC signals that are output to the network analyzer through the anode;
using the network analyzer, measuring a voltage of the reflected AC signal at each of the applied frequencies; and
using a processor coupled to the network analyzer, converting the measured voltages to a value of the complex impedance of the plasma.

2. The method according to claim 1, wherein the anode and the cathode are parallel plates in a parallel plate capacitor.
